(19) United States
(12) Patent Application Publication
(10) Pub. No.: US 2025/0229328 A1
(43) Pub. Date: Jul. 17, 2025

(54) METHOD FOR PRODUCING A COOLING DEVICE

(71) Applicant: Miba Sinter Austria GmbH, Laakirchen (AT)

(72) Inventors: Manuel POHN, Zell am Pettenfirst (AT); Alexander MÜLLER, Altmünster (AT)

(73) Assignee: Miba Sinter Austria GmbH, Laakirchen (AT)

(21) Appl. No.: 18/991,895

(22) Filed: Dec. 23, 2024

(30) Foreign Application Priority Data
Jan. 16, 2024 (AT) A50019/2024

(51) Int. Cl. B22F 5/00; B22F 3/16; B22F 3/17; B22F 3/22; B22F 10/10; B33Y 10/00; H01L 23/367

(52) U.S. Cl. CPC B22F 5/00; B22F 3/16; B22F 3/17; B22F 3/225; B22F 10/10; B33Y 10/00; B22F 2005/005; B22F 2998/10; H01L 23/3677

(57) ABSTRACT

A method for producing a cooling device includes the steps of providing a material and configuring a cooling structure from the material, wherein a metallic powder is used as the material, a green compact being produced from the powder either by metal powder injection molding or by an additive process, which green compact is sintered to form a preform, and the cooling structure in the form of cooling elements is produced from the preform by press forming, for which purpose a part of the preform is pressed through or into a mold, or wherein a green compact is produced from the powder by pressing, wherein the green compact is sintered to form the preform and wherein the cooling structure with the cooling elements is produced by sinter forging.

### CROSS REFERENCE TO RELATED APPLICATIONS

Applicant claims priority under 35 U.S.C. § 119 of Austrian Application No. A50019/2024 filed Jan. 16, 2024, the disclosure of which is incorporated by reference.

### BACKGROUND OF THE INVENTION

### 1. Field of the Invention

The invention relates to a method for producing a cooling device comprising the steps of providing a material and configuring a cooling structure from the material.

### 2. Description of the Related Art

So-called power electronics components, such as power semiconductors, are well known from the state of the art. Such components are frequently used, for example in motor vehicles. It is also known that these components generate large amounts of heat during operation, which often needs to be dissipated using a cooling medium. A wide variety of coolers are known in the prior art for this purpose, including so-called pin fin heat sinks, which are surrounded by a cooling medium and thus transfer the heat from the pins to the cooling medium. DE 10 2019 108 106 A1 describes for example a cooler for a power semiconductor in an inverter, wherein the cooler is configured in two parts and comprises a base plate as a first part, which can be connected to the power semiconductor in a thermally conductive manner; a heat sink as a second part, which is arranged on the base plate, wherein the heat sink has at least one wave-shaped recess, which is formed continuously from a side of the heat sink facing away from the base plate to a side facing the heat sink; wherein the first and second parts are connected to one another and are coated with a layer, which protects both parts from electrochemical reduction.

DE 10 2018 216 859 A1 discloses a device for cooling components, including a first and a second base body; cylindrical and/or conical first cooling fins which are configured in the first base body and around which a coolant can flow, and cylindrical and/or conical second cooling fins which are configured in the second base body and around which the coolant can flow, the second base body being joined to the first base body in such a way that the second cooling fins come to lie between the first cooling fins without touching the first base body.

### SUMMARY OF THE INVENTION

The present invention is based on the object of producing a cooling device for components in a resource-saving manner.

The object of the invention is solved by the method mentioned at the beginning, which provides using a metallic powder as the material, a green compact being produced from the powder either by means of metal powder injection molding or by means of an additive process, which green compact is sintered to form a preform, and the cooling structure in the form of cooling elements is produced from the preform by press forming, for which purpose a part of the preform is pressed through or into a mold, or wherein a green compact is produced from the powder by pressing, the green compact is sintered to form the preform and the cooling structure with the cooling elements is produced by sinter forging.

The advantage here is that the forming of the base element to the cooling elements means that no waste material is produced for their production, as is the case with machining, for example. In addition, all cooling elements of the cooling device can be produced at the same time, which may lead to a corresponding increase in productivity. The advantage for forming is that the preform, although it already has a corresponding strength due to sintering, is easier to form due to the pores compared to a solid material. By producing the preform using metal injection molding or an additive process, various complex shapes can also be produced relatively quickly, with additive processes being particularly suitable for very small series.

According to an embodiment variant of the invention, it may be provided that the preform is recompressed and that the cooling structure is configured during the recompression. By combining these steps into a single method step, a corresponding reduction in the production time of the cooling device can be achieved. The advantage here is that the preform can be formed into a cooling structure more easily due to a higher proportion of pores because it has not been recompressed in advance.

According to a further embodiment variant of the invention, it may be provided that the cooling structure is produced by using a perforated plate as a mold in the form of pin-shaped cooling elements. The mold can therefore be configured relatively easily. It is also easy to adapt to different shapes of cooling elements. Surprisingly, despite the large contact surface, demolding the cooling elements by removing the perforated plate does not pose any problems with regard to material breakage, etc.

According to a further embodiment variant of the invention, it may be provided that the surface of the preform on which the cooling structure is configured is produced curved, at least in portions. This improves the “flow behavior” of the material for the production of the cooling structure.

The cooling elements are preferably produced on a base element, wherein the base element has a rear side. A one-piece structure of the cooling device can thus be produced.

According to an embodiment variant of the invention, it may be provided that the base element has a maximum element height of 3 mm. The advantage of this is that the thin element thickness (also referred to as element height) of the base element compared to known cooling devices means that heat exchange can be increased due to a lower thermal resistance. Such a thin plate thickness cannot be produced with conventional technologies, or only at great expense, as conventional technologies use machining processes. For machining, however, the cooling plates must have a certain minimum thickness in order to be clamped. On the other hand, the materials used in conventional methods have a higher stiffness compared to sintered materials of the same composition, which counteracts forming. These limitations can be avoided with the method according to the invention, which means that cooling devices with a thin element thickness of the base element can also be produced.

According to an embodiment variant of the invention, at least one stiffening element may be arranged to increase the flexural strength of the base element. This is preferably arranged on the first surface of the base element, on which the cooling elements are also located. This may achieve the additional effect that the stiffening element can further improve the cooling performance of the cooling device.

According to a further embodiment variant of the invention, it may be provided that the rear side of the base element is configured with a curvature so that the base element is provided with a prestress. The advantage of this is that the prestress or curvature of the base element can prevent distortion of the power electronics or the component to be connected to the cooling device that may occur during a soldering process or, conversely, deformation or distortion of the cooling device caused by the effect of temperature. This prevents a reduction in the contact surface between the cooling device and the power electronics or the component and the associated drop in performance. Compared to other methods, the configuration of the curvature can be easily integrated into the existing process steps so that no extra process step is required for its production, such as machining the contact surface of the base element to the power electronics or to the component.

According to a further embodiment variant of the invention, it may be provided that at least one auxiliary element is arranged on the rear side for producing a material-formed connection between the cooling device and a component to be cooled with the cooling device. With the help of this auxiliary element, the configuration of the material-formed connection can be better defined, which may also achieve a full-surface abutment between the cooling device and the power electronics or the component and thus an improved heat dissipation. The auxiliary element can be produced in the course of configuring the cooling elements or the preform.

According to a further embodiment variant of the invention, it may be provided that the curvature of the rear side is produced with several different radii of curvature, so that the cooling device can be better adapted to different material-formed connection methods. At the same time, the cooling device may also only be prestressed (higher) in portions, which reduces the influence of prebending on the material of the cooling device.

### BRIEF DESCRIPTION OF THE DRAWINGS

Other objects and features of the invention will become apparent from the following detailed description considered in connection with the accompanying drawings. It is to be understood, however, that the drawings are designed as an illustration only and not as a definition of the limits of the invention.

In the drawings,

FIG. 1 shows a side view of a cooling device with a component to be cooled;

FIG. 2 shows an oblique view of a cooling device;

FIG. 3 shows a side view of an embodiment variant of a cooling device;

FIG. 4 shows a top view of a section of a further embodiment variant of a cooling device;

FIG. 5 shows a top view of a section of a further embodiment variant of a cooling device;

FIG. 6 shows a side view of an embodiment variant of a cooling device;

FIG. 7 shows a further embodiment variant of a cooling device as seen from below;

FIG. 8 shows an oblique view of a further embodiment variant of a cooling device seen from below;

FIG. 9 shows an embodiment variant of a preform; and

FIG. 10 shows an embodiment variant of a tool for producing the cooling device.

### DETAILED DESCRIPTION OF PREFERRED EMBODIMENTS

By way of introduction, it should be noted that in the various embodiments described, the same parts are provided with the same reference signs or the same component designations, wherein the disclosures contained in the entire description can be transferred analogously to the same parts with the same reference signs or the same component designations. Moreover, the specifications of location, such as at the top, at the bottom, at the side, chosen in the description refer to the directly described and depicted figure and in case of a change of position, these specifications of location are to be analogously transferred to the new position.

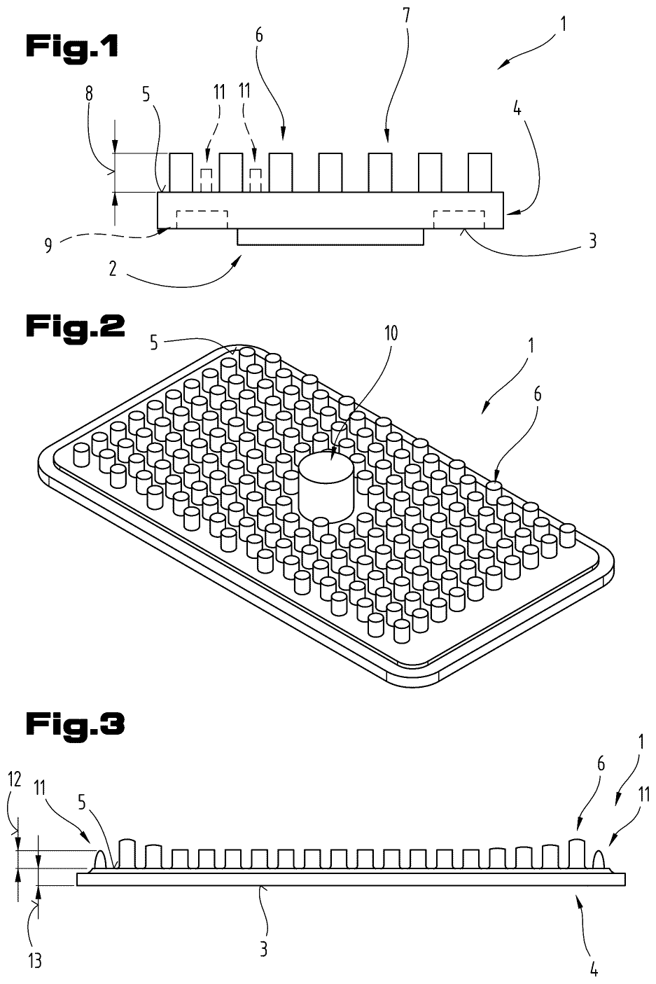

FIG. 1 shows a side view of a cooling device 1.

The cooling device 1 is used to cool a component 2 or several components 2 or an assembly. For this purpose, the cooling device abuts with a rear side 3 against the at least one component 2, in particular directly, and is therefore preferably in direct contact with the component 2 for heat exchange.

The component 2 is preferably an electronic component, in particular a so-called power electronics component or high-performance electronics component or a power semiconductor or high-performance semiconductor. In particular, such components 2 or assemblies made of/with these components 2 may be designed for a power output in the range from several kW up to MW. Such components 2 are used, for example, to convert electrical energy with switching electronic components. Typical applications include converters or frequency converters in the field of electrical drive technology, solar inverters and converters for wind turbines for feeding regeneratively generated energy into the grid or switching power supplies, generally the conversion of AC voltage into DC voltage by rectifiers, the conversion of DC voltage into AC voltage by inverters, control systems, for example in the drive technology of an electric drive in electric vehicles or hybrid vehicles, battery management systems, etc. A power electronics component may, for example, be a semiconductor, in particular a so-called power semiconductor, e.g. an insulated-gate bipolar transistor (IGBT).

Since such components 2 are known in the prior art, reference is made to this prior art in order to avoid repetition of further details.

The cooling device 1 comprises a base element 4, which may also form the rear side 3 of the cooling device 1, and which has a cooling structure on a first surface 5, or consists of the base element 4 and the cooling structure. The cooling structure is formed by cooling elements 6, which are arranged projecting over the first surface 5 on the base element 4 and are integrally connected to it, as may also be seen in FIG. 2. In other words, the cooling device 1 may only be formed by a single piece. Irrespective of this one-piece nature, it is possible within the scope of the invention that several cooling devices 1 may be combined with one another per component 2 or assembly of/with at least one such component 2 to form a cooling device group according to the invention. In particular, cooling devices 1 may therefore also be assembled in a modular way to form a cooling device group.

The base element 4 and the cooling elements 6 are made of or consist of a sintered material or of/with a metallic powder. Furthermore, the cooling elements 6 are produced from the base element 4 by forming.

According to an embodiment variant, the base element 4 and the cooling elements 6 have a density of at least 98%, in particular at least 98.5%, preferably at least 99%, of the full density of the material used.

The full density refers to the density of a cooling device made from the same material using melting metallurgy, i.e. a component made from a solid material. The term “solid material” refers to a metallic material that, with the exception of imperfections, has no pores, as is usually the case with sintered components.

The cooling elements 6 are provided to be surrounded by a cooling fluid, for example water, so that the heat absorbed by the cooling device 1 is removed via this cooling fluid. Preferably, the cooling device 1 is a so-called pin fin cooling device.

The cooling elements 6 of the embodiment variant shown are cylindrical. However, they may also have a different shape, for example a truncated cone shape or generally one with a cross-section that tapers in the direction of a cooling element head 7, for example a truncated pyramid shape.

The cross-section of the cooling elements 6 may be circular, oval, diamond-shaped, square, etc.

Furthermore, all cooling elements 6 may have the same configuration. However, it is also possible to arrange or combine cooling elements 6 with different shapes on a base element 4.

The cooling elements 6 may preferably have a height 8 above the first surface 5 of the base element 4, which is between 2 mm and 20 mm.

In the simplest embodiment of the cooling device 1, all cooling elements 6 of the cooling device 1 have the same height 8 within the tolerances. However, it is possible within the scope of the invention for some of the cooling elements 6 to have a lower height than the rest of the cooling elements 6, as may be seen in FIG. 3, for example. For example, cooling elements 6 at the edges may be higher than the rest or the cooling elements 6 may have a progression of heights from lower or higher in the center of the cooling device 1 to higher or lower at the edge of the cooling device 1. Other embodiments of different heights 8 are possible within the scope of the invention.

Furthermore, it may be provided that between 300 and 1300, in particular between 300 and 1000, for example between 300 and 750, cooling elements 6 are arranged or configured per dm2 of the first surface 5. In particular, this number has proven to be advantageous with regard to the production of the cooling device 1, i.e. the forming of the base element 4 to the cooling elements 6, as damage to the cooling elements 6 or incompletely formed cooling elements 6 may thus be avoided or reduced.

As may be seen in particular from FIG. 1, according to one embodiment variant of the cooling device 1, it may be provided that the rear side 3 of the base element 4 is configured with a flat surface. However, it is also conceivable that the rear side 3 is configured with one or more depressions 9, in which a component 2 is at least partially accommodated. This enables a better connection of the component 2 to the cooling device 1. In general, the component 2 may be glued or screwed or soldered or sintered, etc., to the cooling device 1.

The at least one depression 9 may be produced at the same time as the cooling elements 6. The at least one depression 9 also makes it possible to produce cooling elements 6 whose height 8 is greater than that of the rest of the cooling elements 6.

As may be seen from FIG. 2, the cooling device 1 may have at least one further structural element 10 on the first surface 5 of the base element 4. The structural element 10 is a cylinder in the form shown, but may also have a different cross-sectional area, for example a diamond-shaped one. The structural element 10 may be used to provide a further surface on the cooling device 1 that is above the level of the cooling elements 6. The structural element 10 may therefore have a greater height than the cooling elements 6. However, it is also conceivable for the at least one structural element 10 to have a lower height or the same height as the cooling elements 6. Furthermore, more than one structural element 10 may be arranged, wherein the several structural elements 10 may have the same or a different configuration, e.g. in shape and/or height.

The structural element 10 may, for example, be provided for a screwed connection, as stiffeners or as a spacer or stop.

The structural element 10 is preferably not mechanically reworked, but is pressed in net shape or near net shape quality during the pressing of a preform for the production of the cooling device 1 or is produced by powder metallurgy or by a method according to the invention. The structural element 10 or the structural elements 10 are therefore preferably configured in one piece with the base element 4 and the cooling elements 6.

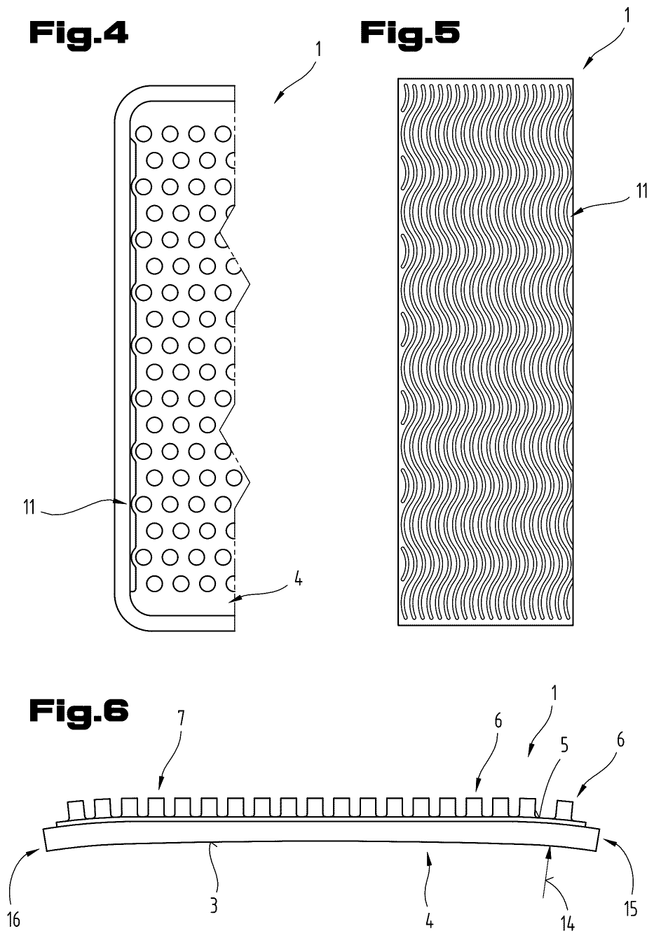

In the embodiment variant shown in FIG. 3, a stiffening element 11 is provided between the end faces and the cooling elements 6 along the wide sides of the base element 4. FIG. 4 shows a section of an embodiment variant of the cooling device 1 in which the stiffening element 11 is arranged continuously around the circumference of the base element 4. As may also be seen from this FIG. 4, the stiffening element 11 may be arranged directly at the edge of the base element 4. FIG. 3 shows that the stiffening element 11 may also be arranged at a distance from the edge of the base element 4.

Furthermore, the stiffening element 11 is rounded in the corner areas of the base element 4 as shown in FIG. 4. However, it may also be configured differently, for example with an inclined course towards the edge or following the corners of the base element 4.

In FIG. 4, the stiffening element 11 is arranged between the edge and the cooling elements 6. As indicated by the stroke-dotted lines in FIG. 1, the stiffening element 11 or stiffening elements 11 may also be arranged between the cooling elements 6, for example also exclusively between the cooling elements 6. With regard to the stiffening elements 11, however, a combination of the embodiment variants according to FIG. 1 and 3 or 4 is also conceivable, so that stiffening elements 11 may be arranged along the edge of the base element 4 and between the cooling elements 6.

The stiffening element 11 may have a rectilinear course, as shown in FIG. 2, for example, or, according to one embodiment variant, a non-rectilinear course, such as a wave-shaped one, as shown in the section of the cooling device 1 in FIG. 5. These wave-shaped stiffening elements 11 may also be arranged in a course between the cooling elements 6. However, in the embodiment variant shown in FIG. 5, the wave-shaped stiffening elements 11 also form the cooling elements 6 of the cooling device 1. According to a further embodiment variant, it may also be provided that the stiffening elements 11 are arranged with a longitudinal extension at least approximately in a flow direction for a cooling fluid through the cooling device 1. This may also be provided in other embodiment variants of the cooling device 1 and is therefore not limited to the embodiment variant shown in FIG. 5. In the embodiment variant shown in FIG. 5, channels for the cooling fluid are configured between the stiffening elements 11.

Preferably, the stiffening elements 11 are lower than the cooling elements 6, especially if they do not also form the cooling elements 6. According to a further embodiment variant, it may be provided that the stiffening element 11 has a height 12 that corresponds to between 20% and 100%, in particular 60% and 90%, of the height 8 or, in the case of cooling elements 6 of different heights, the maximum height 8 in the same direction of the cooling elements 6.

A width of the stiffening element 11 (parallel to the first surface 5 of the base element 4) may be between 0.5 mm and 4 mm.

In principle, the stiffening element 11 may be subsequently attached to the base element 4, for example after the cooling elements 6 have been formed. According to an embodiment variant, however, the stiffening element 11 may be produced during the production of a preform for the production of the cooling device 1. According to another embodiment variant, the stiffening element 11 may be produced from the sintered material by forming from the material of the base element 4, preferably at the same time as the cooling elements 6 are produced from the preform.

The stiffening element 11 or the stiffening elements 11 are therefore preferably configured in one piece with the base element 4 and the cooling elements 6. It is further preferred if the stiffening element 11 or the stiffening elements 11 are produced in net shape or near net shape quality.

The base element 4 may have an element height 13 of between 1 mm and 5 mm. According to an embodiment variant, the base element 4 may have a maximum element height 13 of 3 mm. In particular, the base element 4 may have an element height 13 of between 1 mm and 2.5 mm. The element height 10 of the (plate-shaped) base element 4 is measured between its rear side 3 and the first surface 5. If a depression 9 is provided in the rear side 3, the element height 13 is measured next to the depression 9.

FIG. 6 shows a side view of an embodiment variant of the cooling device 1. This again is provided with the base element 4, on the first surface 5 of which the cooling structure with the cooling elements 6 is arranged.

In contrast to the embodiment variant of the cooling device 1 according to FIG. 1, in this embodiment variant according to FIG. 6 the rear side 3 of the base element 4 is provided with a curvature, wherein the base element 4 is prestressed by the production of the curvature.

In the embodiment variant shown, the curvature in relation to the cooling elements 6 has a concave progression. In particular, the base element 4 may have plano-concave configuration. The first surface 5 may also be configured to at least approximately follow the course of the rear side 3 of the base element 4.

The second surface 3 or the entire base element 4 may also have a convex curvature in relation to the cooling elements 6.

The curvature may be configured along the length or width of the base element 4.

The curvature may be configured with a radius of curvature 14 that remains constant over the entire course. According to a further embodiment variant, it may be provided that the curvature has several different radii of curvature 14. In particular, it may be provided that the base element 4 is provided with the curvature with the smallest radius of curvature 14 in opposite edge areas 15, 16.

Preferably, the curvature has a symmetrical configuration from the first edge area 15 to the second edge area 16.

The curvature may, for example, have an elliptical, parabolic, etc. shape. Other shapes are also conceivable.

The cooling elements 6 may be arranged with the same orientation on the curved base element 4. However, the orientation of the cooling elements 6 may also be arranged to follow the curvature of the base element 4. This orientation may be changed in the course of configuring the material-formed connection with the component 2 due to the stress relief in the base element 4 as a result of the heat acting on it, when the curvature of the base element 4 is reduced and, in particular, it is configured to a flat base element 4.

It is also possible for the heights 8 of the cooling elements 6 to be adapted to the curvature so that the cooling element heads 7 are at the same height when the base element 4 is provided with the curvature.

The radius of curvature 12 of the base element 4 may be selected from a range of 250 mm to 5000 mm, in particular from 1000 mm to 4000 mm. A maximum deflection of 1.25 mm over a length of 100 mm or 200 mm may thus be achieved. If the curvature has several different radii of curvature 12, all radii of curvature 12 are preferably also selected from this range.

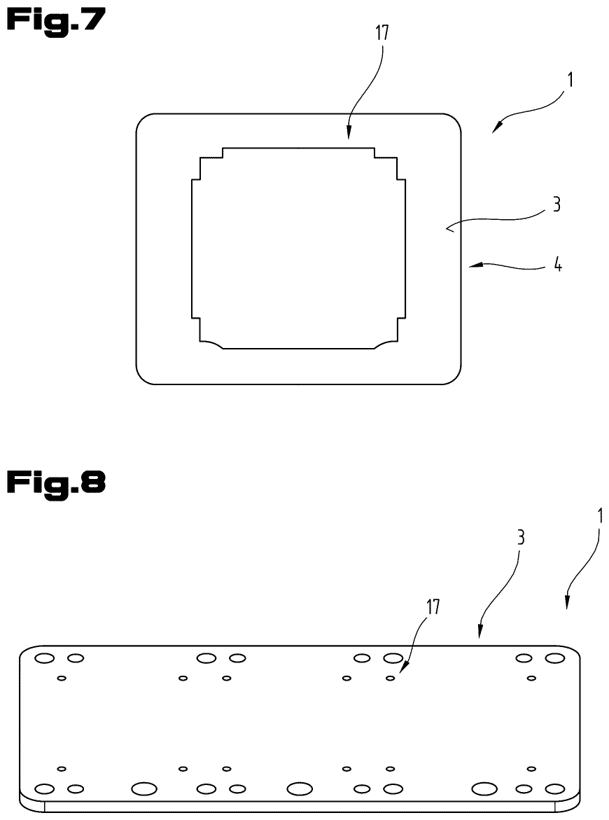

FIG. 7 shows a further embodiment variant of the cooling device 1 as seen from below.

It should be mentioned at this point that the embodiment variants of the cooling device 1 described for the figures may be used independently on their own. Combinations of these embodiment variants are also possible. Therefore, if reference is made below to a flat base element 4, this may also have a curved configuration, for example.

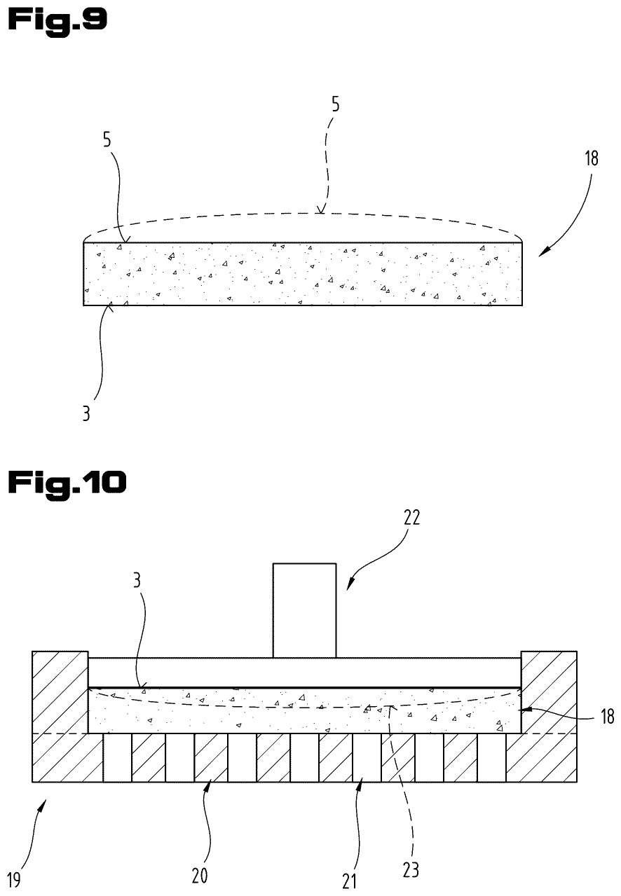

FIG. 7 shows the flat rear side 3 of the base element 4. At least one auxiliary element 17 is arranged on this rear side 3 to create a material-formed connection between the cooling device 1 and the component 2. In the specific embodiment variant shown, the auxiliary element 17 is a depression. However, the auxiliary element 17 may also be a protrusion on the rear side 3, as shown in the embodiment variant shown in FIG. 8.

The depression is used to hold the filler material for the material-formed connection and prevents the molten filler material from running out during the configuration of the material-formed connection between the cooling device 1 and the component 2 (see FIG. 1).

The protrusion, on the other hand, serves to form a gap, in particular a uniform gap, between the cooling device 1 and the component 2, so that the filler material is configured over the connection surface (the surface to which the filler material is applied) with an at least approximately uniform layer thickness, so that there are as few differences as possible in the thermal resistance between the cooling device 1 and the component 2 over the connection surface.

In FIG. 7, only one auxiliary element 17 is shown. However, more than one auxiliary element 17 may also be arranged, for example two, three, four, etc., as may be seen in FIG. 8. However, the number of auxiliary elements 17 specifically shown in FIG. 8 is not to be understood as limiting the invention. In particular, their number may depend on the size of the base element 4.

Furthermore, the multiple auxiliary elements 17 are not limited to protrusions. Several discrete depressions distributed over the rear side 3 may also be provided as auxiliary elements 17.

Combinations of depressions and protrusions as auxiliary elements 17 on the rear side 3 of the base element 4 are also possible within the scope of the invention.

In top view, the depressions may have a circular, elliptical, oval, generally round, triangular, square, pentagonal, etc. configuration. More complex shapes are also possible, as may be seen from the example of a depression in FIG. 7.

The depression may have a maximum depth of between 0.05 mm and 0.5 mm. Below 0.05 mm, the configuration of the depression is more susceptible to errors in the connection formation, as the depression may not be filled with the filler material. With a depth of more than 0.5 mm, the gap between the cooling device and the component in which the material-formed connection is configured may change too much, so that a uniform connection layer may not be formed.

Preferably, if there are several depressions on the rear side of the base element 4, they are all configured in the same way. However, several differently configured depressions may also be provided.

The at least one protrusion may have a maximum height of between 0.05 mm and 0.5 mm. As with the depression, a height of less than 0.05 mm may be too small for the gap thickness to form a uniform connection layer. On the other hand, with a height of more than 0.5 mm, the connection layer may be too thick, which may impair heat dissipation. In addition, if the gap thickness is more than 0.5 mm, the liquid filler material may flow out of the connection area, creating the risk of an uneven connection layer.

If there are several depressions, they may all have the same configuration. Likewise, differently configured protrusions may be provided on the rear side 3 of the base element 4.

The protrusion or protrusions may have a nub-shaped, web-shaped, etc., configuration. They may, for example, have a round, oval, elliptical, generally round, triangular, square, etc., cross-section when viewed from above.

The protrusion may have a length of between 5 mm and the total length of the base element 4. Furthermore, the protrusion may have a width of between 5 mm and the total width of the base element 4.

The depression or depressions may have a total surface area of between 0.1% and 50% of the surface area of the rear side 3 of the base element 4.

The connection layer between the cooling device 1 and the component 2 may have a layer thickness of between 0.01 mm and 0.5 mm.

The at least one auxiliary element 17 may also be produced by powder metallurgy or by a method according to the invention and may be configured in one piece with the base element 4. For example, the at least one auxiliary element 17 may be produced in the course of configuring the cooling elements 6.

A sintering powder or a powder used in powder metallurgy, in particular a metallic powder or a powder in general, is used to produce the cooling device 1. A metallic powder with good thermal conductivity is preferred. In particular, a powder based on aluminum or an aluminum alloy or based on copper or a copper alloy or a MMC (metal matrix composite) powder is used.

The cooling device 1 may be produced by powder metallurgy using a powder metallurgy method, so that the cooling device 1 may also be a sintered component. For this purpose, a green compact may be produced in a corresponding press mold (die) from a powder, which may be produced from the individual (metallic) powders by mixing, wherein the powders may be used pre-alloyed if necessary, with powdery additives, such as a binder. Preferably, the green compact has a density of at least 80%, in particular between 80% and 96%, of the full density of the material.

However, the green compact may also be produced in a different way. In particular, the green compact may be produced using a metal injection molding (MIM) method or an additive method. For example, the green compact may be produced using any of the additive methods known to date, such as laser powder bed fusion, selective laser sintering, electron beam powder bed fusion, selective laser sintering, binder jetting, direct energy deposition, mold jet method, fused deposition molding, stereolithography method and other method. Preferably, the cold metal fusion (CMF) method is used as an additive method. As this methods as such are known, reference is made to the relevant state of the art.

The green compact is then dewaxed at normal temperatures and sintered in one or two stages or in several stages and then cooled, preferably to room temperature. Sintering may take place at a temperature between 500° C. and 1300° C., for example.

Since the sintering of metallic green compacts and the method parameters used are also known from the prior art, reference is made to the relevant prior art in order to avoid repetition.

Sintering produces a preform 18 from the green compact, as shown as an example in FIG. 9. The preform 18 may be configured as a flat plate, so that the rear side 3 and the first surface 5 may run parallel to each other.

According to an embodiment variant of the method, it may be provided that the first surface 5 of the preform 18, on which the cooling structure is configured, is produced curved, at least in portions. Other shapes of the first surface of the preform 18 are possible with regard to improved formability of the preform 18. This means that the first pin fin projections or cooling element projections (circular, oval, elliptical, etc.) with a height of between 0.1 mm and 2.0 mm may already be preformed. In addition, structures (waves, ribs, etc.) may be deliberately introduced into the first surface 5 of the preform 18 in order to increase the turbulence of a cooling fluid if necessary.

The preform 18 may subsequently be recompressed. Preferably, however, the recompression takes place at the same time as the preform 18 is formed to the cooling elements 6.

The forming of the preform 18 is realized in a mold 19. For this purpose, the preform 18 is inserted into or placed against the mold 19. In the simplest case, the mold 19 is formed by a perforated plate 20. The perforated plate 20 has recesses 21, in particular apertures, into or through which some of the material of the preform 18 is pressed, forming the cooling elements 6. The rest of the material of the preform 18, which is not pressed into or through the mold 19, forms the base element 4.

The recesses 21, i.e. their cross-section, are adapted accordingly to the cross-section of the cooling elements 6 to be produced.

The mold 19 may also look different, so it does not necessarily have to be a simple perforated plate 20. In particular, the mold 19 may have a “pot-shaped” configuration as a die.

If at least one further structural element 10 is present, this may be taken into account by means of a corresponding recess or a corresponding aperture in the mold 19.

For forming, a punch 22 may be applied to the rear side 3 of the preform 18, which also forms the rear side 3 of the base element 4, and pressed onto the preform 18 with a predeterminable pressure. For example, forming may take place at a pressure of between 700 MPa and 1600 MPa. Furthermore, forming may take place during a time of up to 10 seconds, in particular between 0.1 seconds and 10 seconds. Furthermore, the forming preferably takes place at room temperature (20° C.), i.e. cold, or the forming may also take place after preheating the preform 18 to a temperature between 50° C. and 300° C., for example between 50° C. and 150° C., and/or in/with a mold 19 heated to a temperature between50° C. and 300° C., for example between 50° C. and 150° C.

As an alternative to this method, the preform 18 may also be formed to the base element 4 with the cooling elements 6 by sinter forging. The temperature during sinter forging may be between 500° C. and 900° C., for which the preform 18 in particular is heated to this temperature. Alternatively or additionally, a mold in which the preform 18 may be arranged during sinter forging may also be heated to this temperature.

After the shaping, i.e. the forming of the preform 18, the cooling device 1 may be finished. However, it is also possible to post-process the cooling device 1. For example, the cooling elements 6 may be height-calibrated or generally recompressed, for which a punch may also be used. In addition, the first surface 5 and the cooling elements 6 may be provided with a corrosion-resistant coating, for example with an electrodeposited Ni-P coating.

The at least auxiliary element 17 may also be produced in the course of post-processing. It may also be produced during powder pressing before sintering. In this case, the punch 22 must have corresponding recesses or protrusions so that the auxiliary elements 17 are not crushed during forming of the preform 18.

Furthermore, the at least one auxiliary element 17 may be produced at the same time as the preform 18 is formed. For this purpose, the punch 22 may have a protrusion on an abutment surface that may be placed against the preform 18 to form the depression described above in the rear side 3 of the base element 4 and/or a depression to form the protrusion described above on the rear side 3 of the base element 4. The number of protrusions and/or depressions on the punch 22 depends on the number of auxiliary elements 17 to be produced.

It may also be provided that the at least one auxiliary element 17 is produced during the height calibration of the cooling elements 6. For this purpose, a supporting surface of a mold or a clamping element, on which the base element 4 is placed for height calibration, has the corresponding protrusions or depressions.

It should be mentioned at this point that the preform 18 may be formed in one or more stages. In the multi-stage embodiment, the cooling elements 6 are not formed in one step, but in several steps. Particularly in the multi-stage embodiment variant, it may be advantageous if the auxiliary element 17 is formed in the course of any height calibration of the cooling elements 6.

The curvature of the base element 4 described above may also be carried out in the course of forming the preform 18 or in the course of the height calibration of the cooling elements 6 that may have to be carried out. In FIG. 7, a curved abutment surface 23 of the punch 22 is in outlines shown as a stroke-dotted line. The curvature of the abutment surface 23 is inverse to the curvature of the base element 4 to be produced. This means that no machining is required to configure the curvature of the base element 4.

The cooling device 1 may be arranged openly on a component 2 to be cooled. According to a further embodiment variant, it is also conceivable for the cooling elements 6 to be arranged in a housing. In this case, the base element 4 may form a bottom element or a cover element of the housing. In particular with the bottom element, the cooling device 1 may be arranged adjacent to the component 2, in particular directly adjacent to it. It is also possible for cooling elements 6 to be arranged on the bottom element and further cooling elements 6 on the cover element, wherein the cooling elements of the bottom element and the cooling elements of the cover element together form the cooling structure. For example, the cooling element 6 of the cover element may be arranged in gaps between the cooling elements 6 of the bottom element. In this case, the bottom element with a part of the cooling elements 6 is produced from a preform 18 and the cover element with the rest of the cooling elements 6 is produced from a further preform according to any of the methods mentioned above.

It should be mentioned at this point that although a method of producing the cooling device 1 is claimed, independent protection may be claimed for the cooling device 1 itself, irrespective of the method of production.

The exemplary embodiments show possible embodiment variants, wherein it should be noted at this point that combinations of the individual embodiment variants with one another are also possible.

Finally, for the sake of order, it should be noted that for a better understanding of the structure of the cooling device 1 or the mold 19, these are not necessarily shown to scale.

Although only a few embodiments of the present invention have been shown and described, it is to be understood that many changes and modifications may be made thereunto without departing from the spirit and scope of the invention.

### REFERENCE SIGNS LIST

1 cooling device
2 component
3 rear side
4 base member
5 surface
6 cooling element
7 cooling element head
8 height
9 depression
10 structural element
11 stiffening element
12 height
13 element height
14 curvature radius
15 edge area
16 edge area
17 auxiliary element
18 preform
19 mold
20 perforated plate
21 recess
22 punch
23 abutment area

What is claimed is:

1. A method for producing a cooling device (1) comprising the steps of providing a material and configuring a cooling structure from the material, wherein a metallic powder is used as the material, a green compact being produced from the powder either by means of metal powder injection molding or by means of an additive process, which green compact is sintered to form a preform (18), and the cooling structure in the form of cooling elements (6) is produced from the preform (18) by press forming, for which purpose a part of the preform (18) is pressed through or into a mold (19), or wherein a green compact is produced from the powder by pressing, wherein the green compact is sintered to form the preform (18) and wherein the cooling structure with the cooling elements (6) is produced by sinter forging.

2. The method according to claim 1, wherein the preform (18) is recompressed and wherein the cooling structure is configured during the recompression.

3. The method according to claim 1, wherein the cooling structure is produced by using a perforated plate (20) as a mold (19) in the form of pin-shaped cooling elements (6).

4. The method according to claim 1, wherein the surface of the preform (18), on which the cooling structure is configured, is produced curved at least in portions.

5. The method according to claim 1, wherein the cooling elements (6) are produced on a base element (4), the base element being produced with a rear side (3).

6. The method according to claim 5, wherein the base element (4) has an element height (13) of at most 3 mm.

7. The method according to claim 5, wherein at least one stiffening element (11) is arranged on a first surface (5) of the base element (4) on which the cooling structure is arranged.

8. The method according to claim 5, wherein the rear side (3) of the base element (4) is configured with a curvature so that the base element (4) is provided with a prestress.

9. The method according to claim 5, wherein at least one auxiliary element (17) is arranged on the rear side (3) for producing a material-formed connection between the cooling device (1) and a component (2) to be cooled with the cooling device (1).

10. The method according to claim 5, wherein the curvature of the rear side (3) is produced with several different radii of curvature (14).
